(19) United States
(12) Patent Application Publication
(10) Pub. No.: US 2021/0135109 A1
(43) Pub. Date: May 6, 2021

(54) ACCELERATED THERMAL CROSSLINKING OF PVDF-HFP VIA ADDITION OF ORGANIC BASES, AND THE USAGE OF CROSSLINKED PVDF-HFP AS GATE DIELECTRIC MATERIAL FOR OTFT DEVICES

(71) Applicant: Corning Incorporated, Corning, NY (US)

(72) Inventors: Mingqian He, Horseheads, NY (US); Yang Li, Shanghai (CN); Karan Mehrotra, Painted Post, NY (US); Hongxiang Wang, Shanghai (CN)

(21) Appl. No.: 16/635,690

(22) PCT Filed: Jul. 30, 2018
(86) PCT No.: PCT/US2018/044374

§ 371 Date: Jan. 31, 2020

Related U.S. Application Data
(60) Provisional application No. 62/539,071, filed on Jul. 31, 2017.

(51) Int. Cl. H01L 51/00; C08G 61/12; C09D 127/20

(52) U.S. Cl. CPC H01L 51/004; C08G 61/126; H01L 51/0036; C09D 127/20; H01L 51/0043; C08G 2261/92; H01L 51/052; C08G 2261/364; C08G 2261/344; C08G 2261/3243; H01L 51/0003; H01L 51/0028; C08G 2261/512

(57) ABSTRACT

The present disclosure describes a method of crosslinking fluoroelastomers, or more precisely thermally-crosslinkable fluorine-containing polymers, and to devices such as OTFTs (organic thin film transistors) incorporating such polymers. In some embodiments, a method comprises mixing: a solvent, a thermally crosslinkable fluorine-containing polymer, and one or more organic bases to form a mixed solution. The mixed solution is deposited over a substrate to form a first layer. The first layer is then crosslinked by thermal treatment to form a crosslinked first layer. The polymer is selected from: homopolymers of vinylidene fluoride; and copolymers of vinylidene fluoride with fluorine-containing ethylenic monomers. The one or more organic bases each have a pKa of 10 to 14.

This application claims the benefit of priority under 35 U.S.C. § 119 of U.S. Provisional Application Ser. No. 62/539,071 filed on Jul. 31, 2017, the content of which is relied upon and incorporated herein by reference in its entirety.

### BACKGROUND

Commercial available fluoroelastomers were initially developed by DuPont in 1950s to 1970s. Fluoroelastomers are highly fluorinated polymers which are extremely resistant to oxidative attack, flame, chemicals, solvents and compression set. Their stability has been attributed to the strength of the carbon-fluorine bond compared to that of the carbon-carbon bond, to steric hindrance, and to strong van der Waals forces. Thus, fluoroelastomers find uses in many application fields such as automotive, aerospace, military, chemical, oil well and other industries where the harsh environment and increasing severity of operating conditions necessitate the use of a stable elastomer.

One potential application of fluoroelastomers is use as a gate dielectric insulating layer in an OTFT (organic thin film transistor). A recent paper from the group of Professor Zhenan Bao in Stanford University, Wang et al., Significance of the double-layer capacitor effect in polar rubbery dielectrics and exceptionally stable low-voltage high transconductance organic transistors, Sci. Rep. 2015, 5, 17849, reported an OTFT device combining organic semiconductors, and the fluoroelastomer e-PVDF-HFP used as a gate dielectric insulating layer. But, the processing of e-PVDF-HFP described in Bao's paper, as well as the processing described in related patent application US WO 2016003523, is not practical: the batch-wise procedure takes around 6 hours and up to 180° C. to cure the elastomer, which is too long to be accepted for an economic industrial process.

### BRIEF SUMMARY OF THE INVENTION

The disclosure relates to thermally crosslinked fluorine containing polymers and methods of preparing such polymers, where an organic base is present during thermal crosslinking. The crosslinked polymers exhibit surprisingly good properties as dielectric materials. Transistors fabricated using the crosslinked polymers exhibit surprisingly good properties when compared to otherwise similar transistors where an organic base is not present as described herein during crosslinking.

In some embodiments, a method comprises mixing: a solvent, a thermally crosslinkable fluorine-containing polymer, and one or more organic bases to form a mixed solution. The mixed solution is deposited over a substrate to form a first layer. The first layer is then crosslinked by thermal treatment to form a crosslinked first layer. The polymer is selected from: homopolymers of vinylidene fluoride; and copolymers of vinylidene fluoride with fluorine-containing ethylenic monomers. The one or more organic bases each have a pKa of 10 to 14.

In some embodiments, in the embodiments of any of the preceding paragraphs, the fluorine-containing polymer is a copolymer of vinylidene fluoride with one or more fluorine-containing ethylenic monomers.

In some embodiments, in the embodiments of any of the preceding paragraphs, the one or more fluorine-containing ethylenic monomers are represented by formula (1) or formula (2):

CF₂═CF—R_{f1} (formula (1))

wherein:
R_{f1} is selected from: —F; —CF₃, and —OR_{f2}; and
R_{f2} is a perfluoroalkyl group having 1 to 5 carbon atoms.

CX₂═CY—R_{f3} (formula (2))

wherein:
X is —H, or —F, or a halogen atom;
Y is —H, or —F, or a halogen atom; and
R_{f3} is —H, or —F, a perfluoroalkyl group having 1 to 5 carbon atoms, or a polyfluoroalkyl group having 1 to 5 carbon atoms.

In some embodiments, in the embodiments of any of the preceding paragraphs, the one or more fluorine-containing ethylenic monomers are selected from: tetrafluoroethylene (TFE), chlorotrifluoroethylene (CTFE),trifluoroethylene, hexafluoropropylene (HFP), trifluoropropylene, tetrafluoropropylene, pentafluoropropylene, trifluorobutene, tetrafluoroisobutene, perfluoro(alkyl vinyl ether) (PAVE), and combinations thereof.

In some embodiments, in the embodiments of any of the preceding paragraphs, the fluorine-containing polymer is poly(vinylidene fluoride-co-hexafluoropropylene) (PVDF-HFP).

In some embodiments, in the embodiments of any of the preceding paragraphs, the molar fraction of VDF units in the fluorine-containing polymer is 0.05 to 0.95.

In some embodiments, in the embodiments of any of the preceding paragraphs, the one or more organic bases each have the formula:

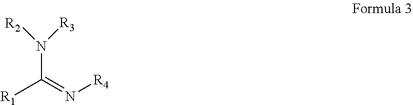

wherein:
the organic base has a molecular weight of 1000 or less;
R₁ and R₂ form a C₂-C₁₂ alkylene bridge, or independently of one another are C₁-C₁₈ alkyls;
R₃ and R₄, independent from R₁ and R₂, form a C₂-C₁₂ bridge, or independently of one another are C₁-C₁₈ alkyls.

In some embodiments, in the embodiments of any of the preceding paragraphs, the one or more organic bases are selected from: 1,8-Diazabicyclo[5.4.0]undec-7-ene, (DBU); 1,5-Diazabicyclo[4.3.0]non-5-ene, (DBN); Tetramethylguanidine, (TMG); Triethylamine, (TEA); Hexamethylenediamine, (HMDA); Methylamine; Dimethylamine; Ethylamine; Azetidine; Isopropylamine; Propylamine; 1.3-Propanediamine; Pyrrolidine; N,N-Dimethylglycine; Butylamine; tert-Butylamine; Piperidine; Choline; Hydroquinone; Cyclohexylamine; Diisopropylamine; Saccharin; o-Cresol; δ-Ephedrine; Butylcyclohexylamine; Undecylamine; 4-Dimethylaminopyridine (DMAP); Diethylenetriamine; 4-Aminophenol; and combinations thereof.

In some embodiments, in the embodiments of any of the preceding paragraphs, the one or more organic bases is 1,8-Diazabicyclo[5.4.0]undec-7-ene, (DBU).

In some embodiments, in the embodiments of any of the preceding paragraphs, the weight ratio between the thermally crosslinkable fluorine-containing polymer and the one or more organic bases in the mixed solution is in the range 1000:2 to 1000:30, or in the range 1000:2 to 1000:20.

In some embodiments, in the embodiments of any of the preceding paragraphs, the mixed solution consists essentially of: the solvent, the thermally crosslinkable fluorine-containing polymer, and the one or more organic bases.

In some embodiments, in the embodiments of any of the preceding paragraphs, the mixed solution further comprises bisphenol-AF.

In some embodiments, in the embodiments of any of the preceding paragraphs, the thermal treatment comprises exposing the first layer to a temperature of 80° C. to 170° C. for 0.5 to 5 hours.

In some embodiments, in the embodiments of any of the preceding paragraphs, the method is a method of forming a transistor, the method further comprising: depositing an organic semiconductor over the substrate, before or after forming the crosslinked first layer, to form a second layer, such that the second layer is in direct contact with the crosslinked first layer; forming a source and a drain in contact with the second layer, before or after forming the second layer, the source and drain defining the ends of a channel through the second layer; forming a gate superposed with the channel, wherein the crosslinked first layer separates the gate from the second layer.

In some embodiments, in the embodiments of any of the preceding paragraphs, the organic semiconductor is an organic semiconductor polymer comprising a diketopyrrolopyrrole fused thiophene polymeric material, wherein the fused thiophene is beta-substituted.

In some embodiments, in the embodiments of any of the preceding paragraphs, the organic semiconductor polymer comprises the repeat unit of formula 1′ or 2′:

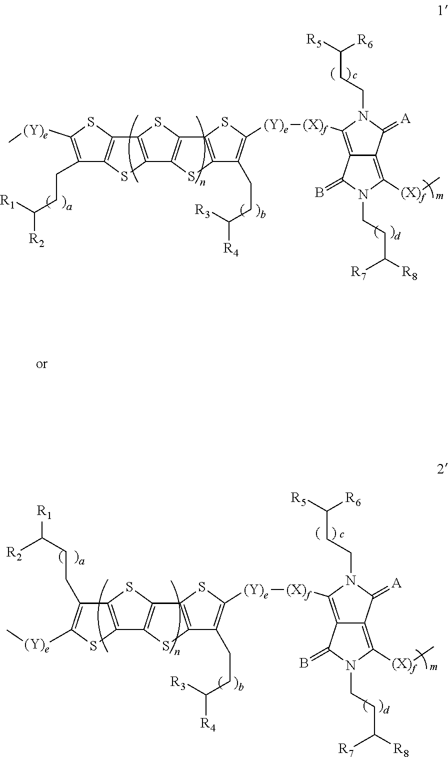

wherein, in the formula 1′ and 2′, m is an integer greater than or equal to one; n is 0, 1, or 2; R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl; a, b, c, and d are independently, integers greater than or equal to 3; e and f are integers greater than or equal to zero; X and Y are, independently a covalent bond, an optionally substituted aryl group, an optionally substituted heteroaryl, an optionally substituted fused aryl or fused heteroaryl group, an alkyne or an alkene; and A and B may be, independently, either S or O, with the provisos that:
i. at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl;
ii. if any of R₁, R₂, R₃, or R₄ is hydrogen, then none of R₅, R₆, R₇, or R₈ are hydrogen;
iii. if any of R₅, R₆, R₇, or R₈ is hydrogen, then none of R₁, R₂, R₃, or R₄ are hydrogen;
iv. e and f cannot both be 0;
v. if either e or f is 0, then c and d, independently, are integers greater than or equal to 5; and
vi. the polymer having a molecular weight, wherein the molecular weight of the polymer is greater than 10,000.

In some embodiments, in the embodiments of any of the preceding paragraphs, the organic semiconductor has formula 3′:

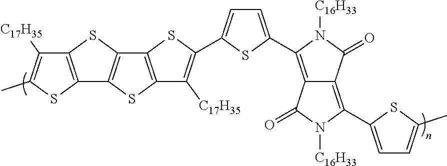

In some embodiments an apparatus comprises a crosslinked first layer disposed over a substrate. The crosslinked first layer formed by the processes of any of the preceding paragraphs.

In some embodiments, in the embodiments of any of the preceding paragraphs, the apparatus is a transistor, the apparatus further comprising: a second layer disposed over or under the crosslinked first layer, the second layer comprising an organic semiconductor, wherein the second layer is in direct contact with the crosslinked first layer; a source and a drain in contact with the second layer, the source and drain defining the ends of a channel through the second layer; and a gate superposed with the channel, wherein the crosslinked first layer separates the gate from the second layer.

In some embodiments, in the embodiments of any of the preceding paragraphs, the capacitance of the transistor is independent from the thickness of the crosslinked first layer.

### BRIEF DESCRIPTION OF THE DRAWINGS/FIGURES

FIG. 1 shows a conventional dielectric structure and a double layer charging dielectric structure.

FIG. 2 shows a bar graph of relaxation time T₂ (in ms) for various samples where DBU was present during crosslinking of an elastomer.

FIG. 3 shows a bar graph of relaxation time T₂ (in ms) for various samples where DBU was present during crosslinking of an elastomer, different from the samples of FIG. 2.

FIG. 4 shows an OTFT structure having the insulator closer to the substrate than the semiconductor.

FIG. 5 shows an OTFT structure having the semiconductor closer to the substrate than the insulator.

FIG. 6 plots the capacitance of various transistors having insulator layers fabricated with various DBU loadings.

### DETAILED DESCRIPTION OF THE INVENTION

Introduction

The present disclosure describes a method of crosslinking fluoroelastomers, or more precisely thermally-crosslinkable fluorine-containing polymers, and to devices such as OTFTs (organic thin film transistors) incorporating such polymers.

It has been discovered that a small amount (<=2%) of organic base having a pKa of 10-14 can significantly accelerate the crosslinking of thermally-crosslinkable fluorine-containing polymers. DBU is an example of such a base. Compared to a similar crosslinking procedure without organic bases, the method using organic bases is able to decrease crosslinking time by up to 80% while simultaneously decreasing crosslinking temperature by up to 30° C.

In some embodiments, a layer of thermally crosslinked fluorine containing polymer is prepared by the following method: A solvent, a thermally crosslinkable fluorine-containing polymer, and one or more organic bases are mixed to form a mixed solution. The mixed solution is deposited over a substrate to form a first layer. The first layer is then crosslinked by thermal treatment to form a crosslinked first layer. The polymer is selected from: homopolymers of vinylidene fluoride; and copolymers of vinylidene fluoride with fluorine-containing ethylenic monomers. The one or more organic bases each have a pKa of 10 to 14.

It has been discovered that a film of crosslinked fluorine-containing polymer formed using such a base has unexpectedly desirable properties. Otherwise similar transistors formed using these films unexpectedly and surprisingly have superior properties, such as higher charge mobility and higher on/off ratio, when compared to otherwise similar transistors formed using films crosslinked without the use of organic base as described herein. These superior properties were demonstrated in transistors using e-PVDF-HFP as the crosslinked fluorine-containing polymer, and PTDPPTFT4 as the organic semiconductor (OSC).

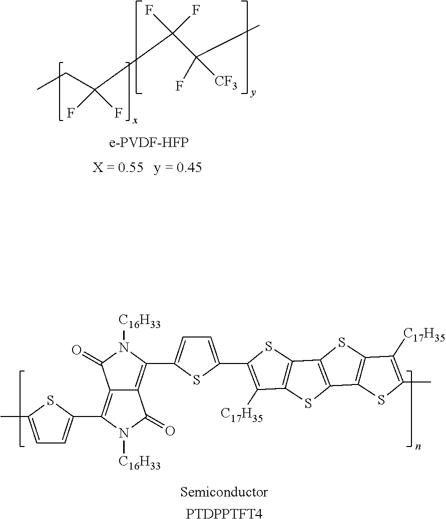

### Organic Bases

It is believed that using organic bases having a pKa similar to DBU in a similar process will lead to a film of crosslinked fluorine-containing polymer also having unexpectedly desirable properties. It is believed that using an organic base with a pKa of 10 to 14 leads to a crosslinked network having a crosslinking density suitable for unexpectedly superior performance as a double-layer dielectric material. Without being limited by theory, it is believed that bases with pKa values lower than 10 would be not strong enough to create the desired C═C double bonds in the polymer backbone, and so may not have sufficient accelerating effect. Bases with pKa values higher than 14 may preferentially create scissor polymers chains over the desired C═C double bonds. It has been observed that DBU has unexpectedly superior properties even when compared to other organic bases having similar pKa.

As used herein, the “pKa” of an organic base or other compound is the acid dissociation constant of that compound measured on a log scale (also known as pKa) at 25° C. It is appreciated that the pKa of a compound may be temperature dependent, and that some of the processes described herein take place at temperatures other than 25° C. Nevertheless, for purposes of determining whether a compound meets the pKa criteria described herein, the pKa of the compound at 25° C. should be compared to the ranges described herein. For example, where the criteria for selecting a suitable organic base is that the base has a pKa of 10 to 14, the pKa of the organic base at 25° C. should be compared to the range 10 to 14 to determine if the base is suitable, even if the process in which the organic base is used involves temperatures other than 25° C. Unless otherwise specified, pKa as described herein is measured in water.

In some embodiments, the organic base may have a pKa of 10, 11, 12, 13 or 14, or any range having any two of these values as endpoints. In some embodiments, the organic base has a pKa of 10 to 14. In some embodiments, the organic base has a pKa of 12 to 14.

In some embodiments, in the embodiments of any of the preceding paragraphs, the one or more organic bases each have the formula of Formula 3, which describes bases having a structure similar to DBU. Organic bases having Formula 3 include those of Table 1:

TABLE 1

| Structural formula | Name | CAS |
|---|---|---|
| 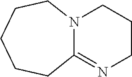 [SMILES: C1CCC2=NCCCN2CC1] | 2,3,4,6,7,8,9,10- octahydropyrimido [1,2-a]azepine | 6674-22-2 |
| 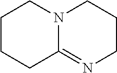 | 3,4,6,7,8,9- hexahydro-2H- pyrido[1,2-a] pyrimidine | 19616-52-5 |
| 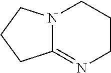 | 2,3,4,6,7,8- hexahydropyrrolo [1,2-a]pyrimidine | 3001-72-7 |
| 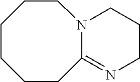 [SMILES: C1CCCN2CCCN=C2CC1] | 3,4,6,7,8,9,10,11- octahydro-2H- pyrimido[1,2-a] azocine | 58379-23-0 |
| 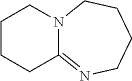 [SMILES: C1CCN2CCCCC2=NC1] | 2,3,4,5,7,8,9,10- octahydropyrido [1,2-a][1,3] diazepine | 106872-83-7 |
| 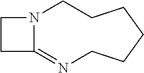 [SMILES: C1CCCN2CC/C2=N/CC1] | (Z)-1,8- diazabicyclo [7.2.0]undec- 8-ene | 341497-13-0 |
| 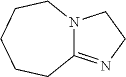 | 2,5,6,7,8,9- hexahydro-3H- imidazo[1,2-a] azepine | 7140-57-0 |
| 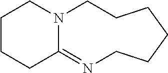 [SMILES: C1CCCN2CCCC/C2=N/CC1] | (Z)- 2,3,4,5,6,7,9,10,11,12- decahydropyrido [1,2-a][1,3]diazonine | 341497-16-3 |
| 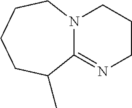 | 10-methyl- 2,3,4,6,7,8,9,10- octahydropyrimido [1,2-a]azepine | 957494-36-9 |
| 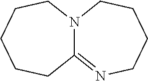 [SMILES: C1CCC2=NCCCCN2CC1] | 2,4,5,7,8,9,10,11- octahydro-3H- azepino[1,2-a] [1,3]diazepine | 52411-85-5 |
| 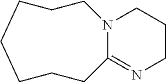 [SMILES: C1CCCC2=NCCCN2CCC1] | 2,3,4,6,7,8,9,10,11,12- decahydropyrimido [1,2-a]azonine | 6664-09-1 |
| 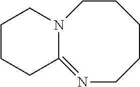 [SMILES: C1CC/N=C2/CCCCN2CC1] | (Z)-3,4,5,6,8,9,10,11- octahydro-2H-pyrido [1,2-a][1,3]diazocine | 850182-40-0 |
| 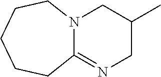 | 3-methyl- 2,3,4,6,7,8,9,10- octahydropyrimido [1,2-a]azepine | 1330045-04-9 |
| 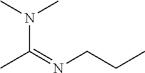 | (Z)-N,N-dimethyl- N′- propylacetimidamide | 94793-20-1 |
| 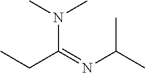 | (Z)-N′-isopropyl- N,N- dimethylpropionimidamide | 112752-57-5 |
| 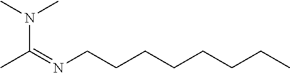 | (Z)-N,N-dimethyl- N′-octylacetimidamide | 103495-46-1 |

Where these bases having a structure similar to DBU also have a pKa of 10-14, such bases are suitable for use in the processes described herein.

In some embodiments, suitable organic bases have a pKa of 10-14. Such bases include: 1,8-Diazabicyclo[5.4.0]undec-7-ene, (DBU); 1,5-Diazabicyclo[4.3.0]non-5-ene, (DBN); Tetramethylguanidine, (TMG); Triethylamine, (TEA); Hexamethylenediamine, (HMDA); Methylamine; Dimethylamine; Ethylamine; Azetidine; Isopropylamine; Propylamine; 1.3-Propanediamine; Pyrrolidine; N,N-Dimethylglycine; Butylamine; tert-Butylamine; Piperidine; Choline; Hydroquinone; Cyclohexylamine; Diisopropylamine; Saccharin; o-Cresol; δ-Ephedrine; Butylcyclohexylamine; Undecylamine; 4-Dimethylaminopyridine (DMAP); Diethylenetriamine; 4-Aminophenol; and combinations thereof.

Some organic bases having a pKa of 10 to 14 are described in Table 2:

TABLE 2

| No. | General name | CAS # | Structure | pKa (25° C., 1 atm) |
|---|---|---|---|---|
| 1 | 1,8-Diazabicyclo[5.4.0] undec-7-ene, DBU | 6674-22-2 | 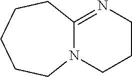 [SMILES: C1CCC2=NCCCN2CC1] | 13.5 ± 1.5 (water), 24.34 (acetonitrile) |
| 2 | 1,5-Diazabicyclo[4.3.0] non-5-ene, DBN | 3001-72-7 | 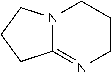 | 13.42 ± 0.20 |
| 3 | Tetramethylguanidine, TMG | 80-70-6 | 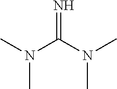 | 13.0 ± 1.0 (water) |
| 4 | Triethylamine, TEA | 121-44-8 | 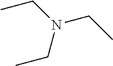 | 10.75 (water), 9.00 (DMSO) |
| 5 | Hexamethylenediamine, HMDA | 124-09-4 | 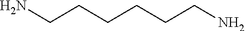 | 10.92 ± 0.10 |

In some embodiments, 1,8-Diazabicyclo[5.4.0]undec-7-ene, (DBU) is particularly preferred for use as the organic base, either alone or in combination with other organic bases, due to the unexpectedly superior results observed when using DBU.

Organic Semiconductor Polymers

It is believed that using other thermally crosslinkable fluorine-containing polymers in a similar process will lead to a film of crosslinked fluorine-containing polymer also having unexpectedly desirable properties. The fluorine-containing polymers are homopolymers or copolymers of vinylidene fluoride, which are well-suited to the base-accelerating approach described herein. This is because it is expected that the organic base will have a similar effect on the crosslinking of such polymers.

For example, the fluorine-containing polymer may be a copolymer of vinylidene fluoride with one or more fluorine-containing ethylenic monomers.

Exceptionally and surprisingly good results were observed when using PTDPPTFT4 as the OSC. Results for OSC having structural similarity to PTDPPTFT4 may be better than those for for OSC not having such similarity. Exemplary fluorine-containing polymers having such structural similarity to PTDPPTFT4 are described by formula (1) and formula (2).

Examples of fluorine-containing ethylenic monomers represented by formula 1 include: tetrafluoroethylene (TFE), hexafluoropropylene (HFP) and perfluoro(alkyl vinyl ether) (PAVE).

Suitable fluorine-containing ethylenic monomers include: tetrafluoroethylene (TFE), chlorotrifluoroethylene (CTFE),trifluoroethylene, hexafluoropropylene (HFP), trifluoropropylene, tetrafluoropropylene, pentafluoropropylene, trifluorobutene, tetrafluoroisobutene, perfluoro(alkyl vinyl ether) (PAVE), and combinations thereof.

In some embodiments, the molar fraction of VDF units in the fluorine-containing polymer may be 0.05, 0.10, 0.15, 0.20, 0.25, 0.30, 0.35, 0.40, 0.45, 0.50, 0.55, 0.60, 0.65, 0.70, 0.75, 0.80, 0.85, 0.90, 0.95, or within any range having any two of these values as endpoints. In some embodiments, the molar fraction of VDF in the fluorine-containing polymer is 0.05 to 0.95. In some embodiments, the molar fraction of VDF in the fluorine-containing polymer is 0.20 to 0.60. If the molar fraction of VDF is too low, there may be too small a ratio of reactive sites to generate the desired C═C double bonds, which would hinder crosslinking. If the molar fraction of VDF is too high, the polymer may have an undesirably high level of crystallinity, which may disable the desirable double layer charging effect.

In some embodiments, the thermally crosslinkable fluorine-containing polymer is crosslinked by a thermal treatment comprising exposure to a temperature of 80° C. to 170° C. for 0.5 to 5 hours. In some embodiments, this thermal treatment is the only exposure of the thermally crosslinkable fluorine-containing polymer to temperatures exceeding 80° C. In some embodiments, the thermally crosslinkable fluorine-containing polymer is not exposed at all to temperatures exceeding 170° C.

Transistors

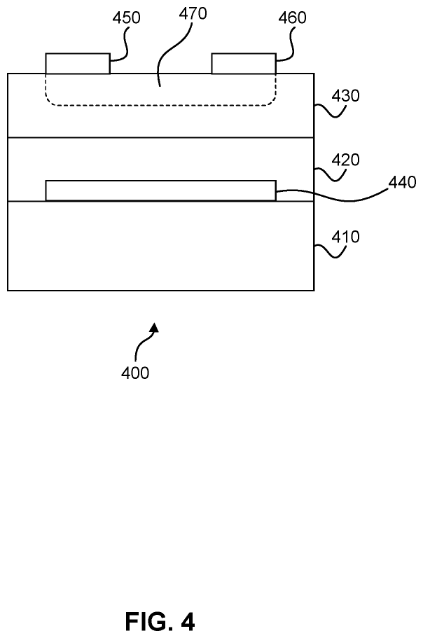

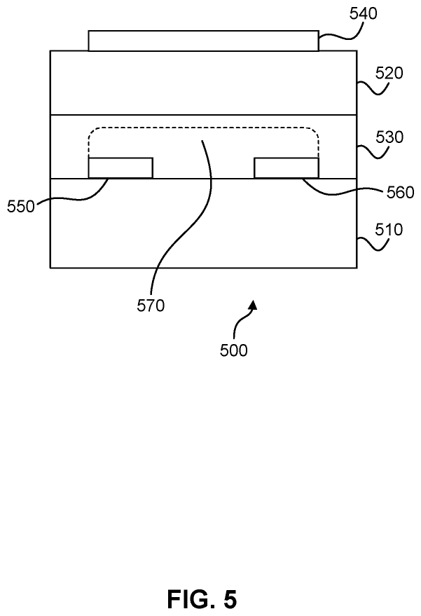

In some embodiments, a transistor may be formed using the thermally crosslinked fluorine-containing polymer as the insulator. Any suitable OTFT transistor structure may be used, including the structures illustrated in FIG. 4 and FIG. 5.

In some embodiments, the transistor uses as a semiconducting layer an organic semiconductor polymer comprising a diketopyrrolopyrrole fused thiophene polymeric material, wherein the fused thiophene is beta-substituted. Suitable OSC polymers include those comprising the repeat unit of formula 1′ or 2′. Particularly good results are observed using an OSC polymer having the structure of formula 3′.

Transistors fabricated as described herein may unexpectedly have a charge mobility of 0.5 cm²/Vs or more when compared to otherwise similar transistors. This charge mobility is unexpectedly good for an OSC transistor using OSC polymers and insulator layers described herein. Such transistors may be suitable for commercial manufacture and for controlling OLED displays, particularly when compared to otherwise similar transistors fabricated without the use of an organic base with a pKa of 10-14 as described herein.

Transistors fabricated as described herein can be used for flexible electronics applications. These applications include EPD (electric paper display), LCD (liquid crystal display) and OLED (organic light emitting device) applications.

Thermal Crosslinking of Fluorine-Containing Polymers

The thermal curing or crosslinking mechanism for thermally crosslinkable fluorine containing polymers such as P(VDF-HFP) has been described and characterized in detail in Schmiegel, W. W., Crosslinking of Elastomeric Vinlylidene Fluoride Copolymers with Nucleophiles. Die Angewandte Makromolekulare Chemie 1979, 76/77, 39-65. In summary, the curing/crosslinking may be divided into two single steps: a) double bond formation in polymer chain, and b) crosslinking formation:

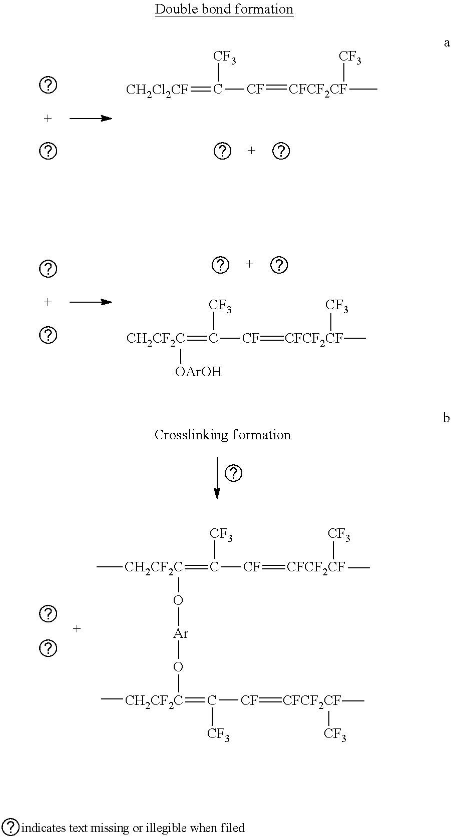

For example, for fluoroelastomer FC 2176 from 3M or DAI-EL G671 from Daikin, components of the crosslinking recipe include the crosslinker hexafluorinated bisphenol-A (Bp-AF) and accelerator, which is an onium (phosphonium, ammonium, etc.) salt in combination with a metal compound as an activator.

In principle, either of the single steps a) double bond formation in polymer chain, and b) crosslinking formation could be the rate limiting step for curing process. Therefore, any additional measures or additives that could help double bond formation or crosslinking formation should increase the efficiency of the curing process, and may be combined with the use of organic base as described herein.

In some embodiments, the mixed solution consists essentially of: the solvent, the thermally crosslinkable fluorine-containing polymer, and the one or more organic bases.

In some embodiments, other components may be added in addition to the solvent, the thermally crosslinkable fluorine-containing polymer, and the one or more organic bases, where the additional components affect the crosslinking process and/or the properties of the crosslinked fluorine-containing polymer. For example, in some embodiments, the mixed solution may further comprise bisphenol-AF. In some embodiments, the mixed solution may contain an onium salt. Exemplary onium salts include phosphonium and ammonium salts. In some embodiments, the mixed solution may contain a metal compound.

Any suitable solvent may be used.

Double Layer Dielectric

Transistors fabricated as described herein, using an organic base with a pKa of 10-14, may benefit from a double layer charging effect. In other words, the capacitance of the transistor may be independent from the thickness of the crosslinked first layer.

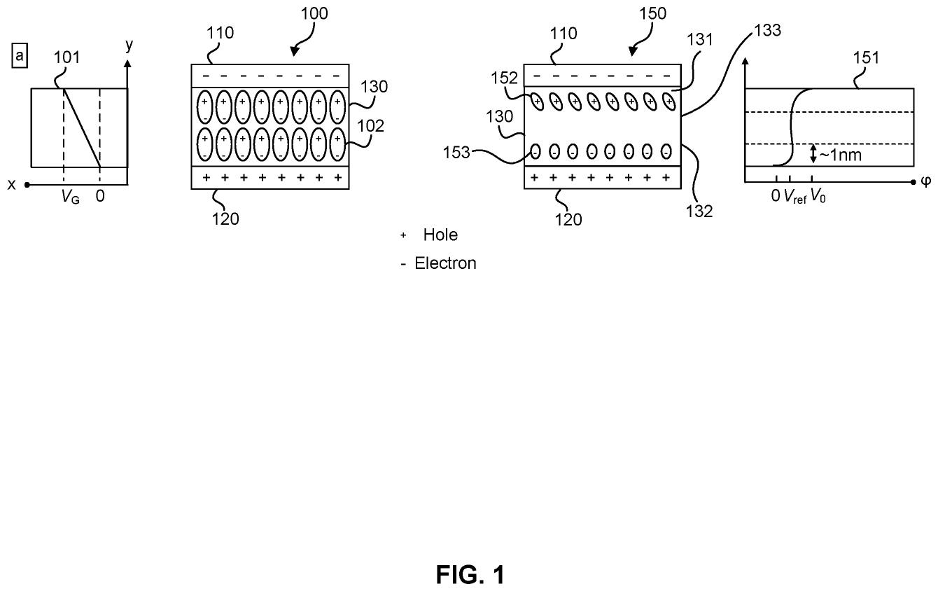

FIG. 1 shows a conventional dielectric structure 100, and a double layer charging dielectric structure 150. Conventional dielectric structure 100 includes a gate 110 and a semiconductor 120, separated by an insulator 130. Similarly, double layer charging dielectric structure 150 includes a gate 110 and a semiconductor 120, separated by an insulator 130.

In conventional dielectric structure 100, when a voltage is applied across insulator 130 by gate 110 and semiconductor 120, dipoles 102 form throughout insulator 130. This dipole formation results in the voltage profile shown in plot 101, which is a plot of voltage V_{G} along the x-axis against position along the y-axis for conventional dielectric structure 100.

In double layer charging dielectric structure 150, when a voltage is applied across insulator 130 by gate 110 and semiconductor 120, an electrical double layer (EDL) forms. The electrical double layer consists of a layer 131 of cations 152 near gate 110, and a layer 132 of anions 153 near semiconductor 120. Layers 131 and 132 are within insulator 130, but only near the interfaces with gate 110 and semiconductor 120, respectively. This EDL results in the voltage profile shown in plot 151, which is a plot of voltage V_{G} along the x-axis against position along the y-axis for double layer charging dielectric structure 150.

The capacitance C of a dielectric structure is proportional to 1/d, where d is the distance over which voltage changes in the dielectric material. As illustrated in FIG. 1, d for the conventional dielectric structure 100 is the thickness of insulator 130. But, for the double layer charging dielectric structure 150, d is the thickness of the EDL, which is an interfacial thickness that is independent of insulator 130. So, for a conventional dielectric material, as illustrated in conventional dielectric structure 100, capacitance C is:

$$C = \frac{{ɛ}_{0} {ɛ}_{t}}{d}$$

But, for a double-layer dielectric material, as illustrated in double layer charging dielectric structure 150, capacitance C is:

$$C = {C}_{E D L} 11 {C}_{E D L} = \frac{1}{2} \frac{{ɛ}_{0} {ɛ}_{t}}{{d}_{E D L}}$$

In the case of conventional dielectric material, d is the thickness of the dielectric material, which is normally several hundred nanometers. But, in the case of the double-layer capacitor, d is d_{EDL}, the thickness of the interface between the OSC and dielectric materials. In this case, d is only several nanometers, even though the thickness of the dielectric material may be much thicker. So, with other conditions unchanged, the double-layer dielectric material is able to provide higher capacitance, which may lead to higher charge carrier mobility and better device performance.

Without being limited by any theories, it is believed that the specific details of how crosslinking is performed in a thermally crosslinkable fluorine-containing polymer can have a dramatic effect on how well the polymer can serve as a double-layer dielectric material. Specifically, it is believed that using an organic base having a pKa of 10-14 to accelerate crosslinking leads to a crosslinked network having a crosslinking density suitable for unexpectedly superior performance as a double-layer dielectric material. It is further believed that the lower temperatures and shorter times enabled by the use of such an organic base may similarly contribute to such a crosslinking density. It is believed that, in the absence of an organic base having a pKa of 10-14, higher crosslinking densities may occur that interfere with ion migration. In other words, DBU and similar organic bases boost the double-layer charging effect of PVDF-HFP and similar fluorinated VDF-based elastomers. When used in an OTFT, this boost increases the capacitance of gate dielectric layers, leading to improved OTFT performance.

This improved performance is commercially significant. An OTFT device employing a dielectric material such as e-PVDF-HFP or other thermally crosslinkable fluorine-containing polymer as the insulating layer, and an OSC such as PTDPPTFT4 or similar materials, is potentially able to drive an OLED display due to its very high transconductance value as high as 0.025/m.

Effect of Organic Base

A recent paper from the group of Professor Zhenan Bao in Stanford University, Wang et al., Significance of the double-layer capacitor effect in polar rubbery dielectrics and exceptionally stable low-voltage high transconductance organic transistors, Sci. Rep. 2015, 5, 17849, reported an OTFT device combining organic semiconductors, and the specific fluoroelastomer e-PVDF-HFP used as a gate dielectric insulating layer. Bao's group did not use an organic base as described herein.

To show the unexpected effect of using an organic base, experiments were performed focusing on thermal crosslinking of the specific P-VDF-HFP grade used in Bao's work. This is a commercial available grade provided by 3M (Dyneon Fluoroelastomer FC 2176, or “C1”). An alternative grade is also available from Daikin (DAI-EL G671).

When using DBU as the organic base in amounts of 2% or less to accelerate crosslinking during OTFT device manufacturing, the device performance improved significantly in terms of charge mobility. However, with higher concentration of DBU, the quality of gate dielectric film became worse and led to non-working OTFT device. These results are shown in Table 3:

TABLE 3

| C1:DBU (mg) | Mobility (cm/Vs) | on/off | Vt (V) |
|---|---|---|---|
| 1000:0 | 0.382 | 1.69 * 10² | −0.86 |
| 1000:5 | 2.46 | 1.91 * 10² | 0.00 |
| 1000:10 | 0.15 | 8.25 * 10¹ | 0.00 |
| 1000:20 | N/A | N/A | N/A |

Table 3 shows that DBU improves polymer crosslinking of PVDF-HFP and similar fluorinated VDF-based elastomers, with weight ratio between fluorinated polymer and base in the range 1000:2 to 1000:500. Similar results are expected for other organic bases having a pKa in the range 10-14.

The weight ratio between fluorinated polymer and base may be 1000:2, 1000:10, 1000:20, 1000:30, 1000:40, 1000:50, 1000:60, 1000:70, 1000:80, 1000:90, 1000:100, 1000:200, 1000:300, 1000:400, 1000:500 or any range having any two of these values as endpoints. In some embodiments, the weight ratio between fluorinated polymer and base is in the range 1000:2 to 1000:500. In some embodiments, this ratio is in the range 1000:2 to 1000:30. In some embodiments, this ratio is in the range 1000:2 to 1000:20. In some embodiments, this ratio is in the range 1000:2 to 1000:10.

Compared to traditionally used SiO₂, using the low Tg e-PVDF-HFP as a gate dielectric insulating layer may provide much higher charge carrier mobility, as well as lower driving voltage and better flexibility. The charge carrier mobility reached its highest value when the OSC material was PTDPPTFT4. Other suitable materials include P3HT (Poly(3-hexylthiophene-2,5-diyl)), PII2T (poly(isoindigo-bithiophene)), Graphene and PCBM ([6,6]-phenyl-C61-butyric acid methyl ester).

Disclosed herein is a DBU (1,5-diaza(5,4,0)undec-5-ene)-accelerated thermal curing process for e-PVDF-HFP with shorter curing time, as well as lower curing temperature. The shorter curing time, lower curing temperature, and superior e-PVDF-HFP properties when cured as described herein result in a process usable in industry where e-PVDF-HFP may be used as a gate dielectric insulating material.

Table 4 shows a performance comparison of OTFT devices using SiO₂ and e-PVDF-HFP, respectively, as the dielectric layer. Both SiO₂ and e-PVDF-HFP devices had similar structures, and both used PTDPPTFT4 as the OSC.

TABLE 4

| | SiO² | | e-PVDF-HFP | |
|---|---|---|---|---|
| Charge Mobility | 1.7 | cm²/Vs) | 35 | cm²/Vs) |
| Transconductance | 0.001 | S/m | 0.02 | S/m |
| Operation voltage | >25 | V | >5 | V |

DBU as the Crosslinking Accelerator in MEK

Based on the crosslinking mechanism, there are two basic steps in the crosslinking process: double bond formation via dehydrofluorination, and crosslinking formation. Thus, increasing double bond formation efficiency should accelerate the crosslinking process. DBU is a strong base but with weak nucleophilicity. Therefore, DBU is a good candidate for dehydrofluorination and double bond formation. Here DBU alone as crosslinking accelerator was tried in MEK. It was found that the mixture was fully gelled even at room temperature with high DBU concentrations (Table 5).

TABLE 5
DBU alone as the crosslinking accelerator at RT

| Sample | DBU1 | | DBU2 | | DBU3 | |
|---|---|---|---|---|---|---|
| DBU | 4.5% | | 9.0% | | 13.5% | |
| Elastomer | 250 | mg | 250 | mg | 250 | mg |
| MEK | 5 | ml | 5 | ml | 5 | ml |
| Gel time | >20 | h (80° C.) | 1 | min (RT) | <1 | min (RT) |

Inspired by the promising results, more trials were carried out to identify the minimum DBU concentration required for efficient gelation at 80° C. (Table 6). It was found out that under the set reaction conditions, DBU's accelerating effect on gelation was not practically important if its concentration was below 7.9%. A sudden increase in gelation rate was observed from 6.8% to 7.9% DBU. There may be a different mechanism that starts occurring between these values that promotes reaction speed.

TABLE 6
DBU alone as the crosslinking accelerator at 80° C.

| Sample | DBU4 | | DBU5 | | DBU6 | | DBU7 | |
|---|---|---|---|---|---|---|---|---|
| DBU | 4.5% | | 5.7% | | 6.8% | | 7.9% | |
| Elastomer | 250 | mg | 250 | mg | 250 | mg | 250 | mg |
| MEK | 5 | ml | 5 | ml | 5 | ml | 5 | ml |
| Gel time (80° C.) | >20 | h | >20 | h | >20 | h | 5 | min |

Subsequently, the gelation reactions were repeated at 150° C. It was discovered that higher temperature could promote the gelation process dramatically with low DBU concentrations (Table 7).

TABLE 7
DBU alone as the crosslinking accelerator at 150° C.

| Sample | DBU8 | | DBU9 | | DBU10 | | DBU11 | | DBU12 | |
|---|---|---|---|---|---|---|---|---|---|---|
| DBU | 2.3% | | 3.4% | | 4.5% | | 5.7% | | 6.8% | |
| Elastomer | 250 | mg | 250 | mg | 250 | mg | 250 | mg | 250 | mg |
| MEK | 5 | ml | 5 | ml | 5 | ml | 5 | ml | 5 | ml |

| | | | | | | | | | |
|---|---|---|---|---|---|---|---|---|---|
| Gel time | >18 | h | >18 | h | 3 h < t < 18 h | 2.5 | h | 2 | h |
| (150° C.) | | | | | | | | | |

In addition to DBU, the use of some other bases was explored. 1,6-Hexamethylenediamine (HMDA), Triethylamine (TEA), 1,4-Diaza[2.2.2]bicyclooctane (DABCO) and Tetramethylguanidine (TMG) were also tried as the crosslinking accelerators of fluoroelastomer. However, they were not efficient as DBU on this crosslinking.

Characterization of Crosslinking Degree by Low-Field NMR with Different DBU Loadings

Low-field NMR is the branch of nuclear magnetic resonance that is not conducted in superconducting high-field magnets. In low-field NMR, the relaxation time of the internal cross-linking chain signal and dangling chain signal is called T₂, which could be further transformed to obtain the so-called ‘crosslinking degree’ of fluoroelastomers. The relaxation time T₂ can also directly reflect the motion characteristics of molecular chain. A small T₂ value represents a well crosslinked system.

Various heating conditions and different DBU loading experiments were performed in solid state. Table 8 shows the thermal crosslinking results of FC 2176 from 3M with different DBU concentrations under different conditions.

TABLE 8
DBU alone as the crosslinking accelerator in solid state

| Sample | 1 | 2 | 3 | 4 | 5 | 6 | 7 | 8 |
|---|---|---|---|---|---|---|---|---|
| DBU | 1% | 1% | 2% | 2% | 3% | 3% | 3% | 3% |
| Elastomer | 1.0 g | 1.0 g | 1.0 g | 1.0 g | 1.0 g | 1.0 g | 1.0 g | 1.0 g |
| MEK | 8 ml | 8 ml | 8 ml | 8 ml | 8 ml | 8 ml | 8 ml | 8 ml |
| Dissolved time | 30 min | 30 min | 30 min | 30 min | 30 min | 30 min | 30 min | 30 min |
| Elastomer | 125 mg/ml | 125 mg/ml | 125 mg/ml | 125 mg/ml | 125 mg/ml | 125 mg/ml | 125 mg/ml | 125 mg/ml |
| Concentration | | | | | | | | |
| Stirring mixture | 10 min | 10 min | 10 min | 10 min | 10 min | 10 min | 10 min | 10 min |
| Standing time | 25 min | 25 min | 25 min | 25 min | 25 min | 25 min | 25 min | 25 min |
| Heating time | 80° C. 1 h | 80° C. 1 h | 80° C. 1 h | 80° C. 1 h | 80° C. | 80° C. 1 h | 80° C. 1 h | 80° C. 1 h |
| | & 150° C. | & 150° C. | & 150° C. | & 150° C. | 1 h | & 150° C. | & 150° C. | & 150° C. |
| | 1 h | 4 h | 1 h | 4 h | | 1 h | 2 h | 4 h |
| Relaxation | 1.03 | 1.11 | 0.82 | 0.90 | 1.35 | 0.85 | 0.87 | 0.93 |
| time(T₂) | | | | | | | | |

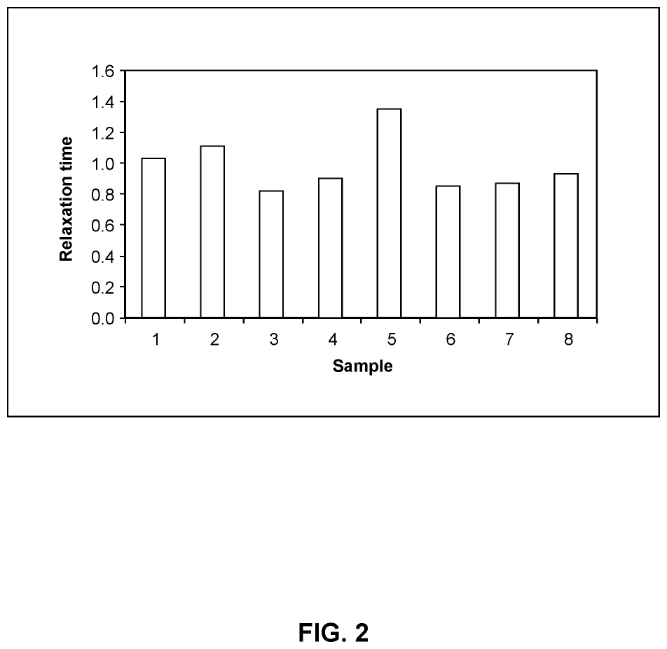

FIG. 2 shows a bar graph of relaxation time T₂ (in ms) for samples 1 through 8. Comparing samples 1 and 2, the data shows that the crosslinking degree decreased mildly as heating time at 150° C. increased. The same phenomenon was also observed with samples 3/4, and samples 6/7/8. It is believed that this decrease in crosslinking was due to the main chain scission reactions caused by the attack of base, DBU in this case. Dry MEK was used as solvent for the preparation of samples 5-8. These films seemed smoother and harder than other films.

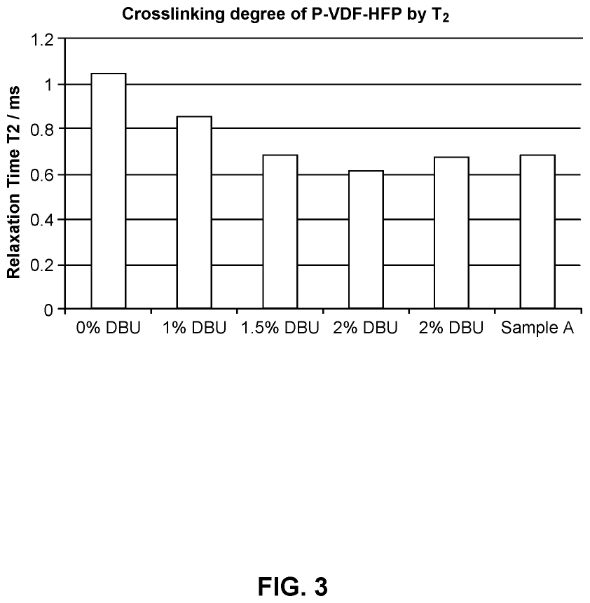

The low-field NMR measurements were repeated several times with different loadings of DBU to evaluate the reproducibility of this method. FIG. 3 shows a bar graph of relaxation time T₂ (in ms) for samples prepared with 0%, 1%, 1.5% and 2% DBU. The samples of FIG. 3 were prepared as follows:
Prepare elastomer solution (3M e-PVDF-HFP, 1 g/MEK 7 ml)
Prepare crosslinking accelerator (DBU 0 to 20 mg/MEK 1 ml, e.g., 20 mg DBU for the 2% DBU samples)
DBU slowly added into elastomer solution
Spin (1 min/1500 rpm) mixing solution on a substrate
Heat the coated substrate
   at 80° C. for 10 min and 180° C. for 6 h for sample A;
   at 80° C. for 10 min and 150° C. for 1 h for all other samples
mechanically remove the crosslinked coating and cut into pieces for low-field NMR measurement
   The two bars for 2% DBU loading show some variability between different samples due to the experimental method used. The observation of a trend of lower relaxation time as DBU loading increases from 0% to 2% is valid. Sample A has zero % DBU loading, and a different heat treatment than the other samples. Sample A corresponds to the DBU loading and heat treatment reported by Professor Zhenan Bao in Stanford University, Wang et al., Significance of the double-layer capacitor effect in polar rubbery dielectrics and exceptionally stable low-voltage high transconductance organic transistors, Sci. Rep. 2015, 5, 17849. It is expected that the data from low-field NMR is reproducible.

OTFT Device Based on the Accelerated Thermal Crosslinking Process

FIG. 4 shows an OTFT structure 400. A gate 440 is disposed over a substrate 410. A crosslinked first layer 420 is disposed on gate 440. Crosslinked first layer 420 may be a fluorine-containing polymer crosslinked as described herein. Crosslinked first layer 420 serves as the insulator of OTFT structure 400. A second layer 430 is disposed over crosslinked first layer 420, and in direct contact with crosslinked first layer 420. Second layer 430 may be an OSC as described herein. Second layer 430 serves as the semiconductor of OTFT structure 400. Source 450 and drain 460 are disposed on and in contact with second layer 430. Source 450 and drain 460 defining the ends of a channel 470 through second layer 430. Gate 440 is superposed with channel 470. Crosslinked first layer 420 separates gate 440 from second layer 430.

FIG. 5 shows an OTFT structure 500. A source 550 and a drain 560 are disposed on substrate 510. Second layer 530 is disposed over substrate 510, source 550 and drain 560. Second layer 530 is in contact with source 550 and drain 560. Second layer 530 may be an OSC as described herein. Second layer 530 serves as the semiconductor of OTFT structure 500. Source 550 and drain 560 defining the ends of a channel 570 through second layer 530. A crosslinked first layer 520 is disposed on second layer 530 and in direct contact with second layer 530. Crosslinked first layer 520 may be a fluorine-containing polymer crosslinked as described herein. Crosslinked first layer 520 serves as the insulator of OTFT structure 500. A gate 540 is disposed on crosslinked first layer 520. Gate 540 is superposed with channel 570. Crosslinked first layer 520 separates gate 540 from second layer 530.

An OTFT structure was fabricated, having the structure shown in FIG. 4. The results described below would be expected for other OTFT structures, for example the structure shown in FIG. 5.

In the fabricated OTFT structure, DBU accelerated thermal crosslinked e-PVDF-HFP was used as the gate dielectric material for OTFT device (crosslinked first layer 420). For second layer 430, an OSC polymer having the following structure was used:

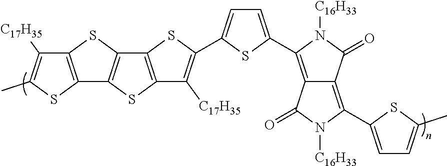

The fabricated OTFT structure was manufactured based on the following procedures:
Deposit Al (100 nm) on Si wafer as gate
Prepare elastomer solution (3M e-PVDF-HFP, 1 g/MEK 7 ml)
Prepare crosslinking accelerator (DBU 20 mg/MEK 1 ml)
DBU slowly added into elastomer solution
Spin (1 min/1500 rpm) mixing solution on Si wafer
Heat the coated Si wafer at 80 C for 10 min and 150 C for 1 h
Spin (1 min/1000) OSC polymer (5 mg/toluene 1 ml) on Si wafer
Heat the Si wafer at 120 C for 10 min
Deposit Au (80 nm) or Al (100 nm) as electrodes (source and drain)

The fabrication process described above was repeated several times, with different ratios of e-PVDF-HFP purchased from 3M (3M) to DBU. Table 9 summarizes the OTFT device performance with various DBU loadings. Table 9 shows that with 0.5% DBU loading, charge mobility increased significantly from 0.382 at 0% DBU loading to 2.46 cm²/Vs at 0.5% DBU loading. Yet with higher loadings of DBU, the device performance dropped dramatically. In the case of 2% DBU, the device showed no detectable performance. This is ascribed to the bad film quality which is probably caused by side reactions between DBU and e-PVDF-HFP. When the crosslinking temperature was increased from 150 to 180 C, with an observably rough and inhomogeneous film. This rough and inhomogeneous film was was probably also the reason for higher on/off ratio observed at higher DBU loadings.

TABLE 9
OTFT device performance with different DBU loadings, setting:
V_{D}: −1V, V_{G}: −5~2V

| 3M:DBU (mg) | Mobility(cm²/Vs) | on/off | Vt (V) |
|---|---|---|---|
| 1000:0 | 0.382 | 1.69 * 10³ | −0.86 |
| 1000:5 | 2.46 | 1.91 * 10² | 0.00 |
| 1000:10 | 0.15 | 8.25 * 10¹ | 0.00 |
| 1000:20 | N/A | N/A | N/A |

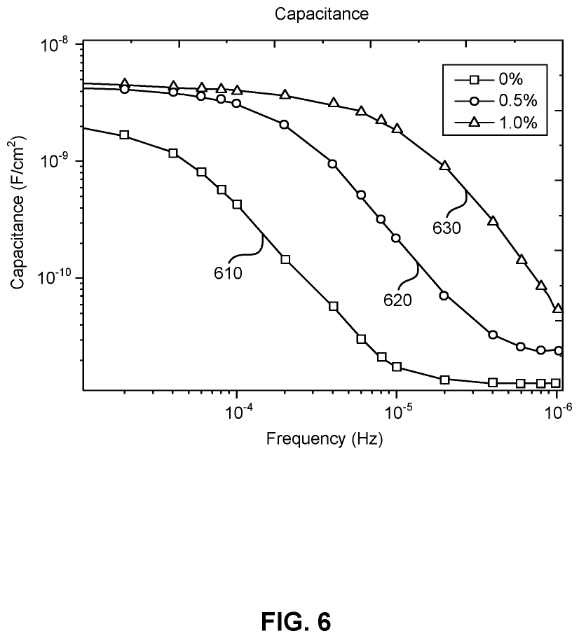

Further investigation found out that addition of DBU could increase film capacitance significantly, especially at high frequencies. Table 10 shows film capacitance (F/cm²) for various DBU loadings. FIG. 6 plots the capacitance for DBU loadings of 0% (line 610), 0.5% (line 620) and 1.0% (line 630).

TABLE 10
Capacitance measured at different frequencies and DBU loadings

| Freq. | 1000:0 | 1000:5 | 1000:10 | 1000:20 |
|---|---|---|---|---|
| 20 | 6.2787 * 10⁻⁹ | 6.6978 * 10⁻⁹ | 9.9201 * 10⁻⁹ | N/A |
| 1 * 10² | 2.2738 * 10⁻⁹ | 4.9319 * 10⁻⁹ | 6.5717 * 10⁻⁹ | N/A |
| 1 * 10³ | 1.9641 * 10⁻⁹ | 4.3197 * 10⁻⁹ | 4.7166 * 10⁻⁹ | N/A |
| 1 * 10⁴ | 4.2917 * 10⁻¹⁰ | 3.1357 * 10⁻⁹ | 4.0018 * 10⁻⁹ | N/A |
| 1 * 10⁵ | 1.7560 * 10⁻¹¹ | 2.2038 * 10⁻¹⁰ | 1.8914 * 10⁻⁹ | N/A |
| 1 * 10⁶ | 1.2839 * 10⁻¹¹ | 2.3998 * 10⁻¹¹ | 5.5605 * 10⁻¹⁰ | N/A |

While various embodiments have been described herein, they have been presented by way of example, and not limitation. It should be apparent that adaptations and modifications are intended to be within the meaning and range of equivalents of the disclosed embodiments, based on the teaching and guidance presented herein. It therefore will be apparent to one skilled in the art that various changes in form and detail can be made to the embodiments disclosed herein without departing from the spirit and scope of the present disclosure. The elements of the embodiments presented herein are not necessarily mutually exclusive, but may be interchanged to meet various situations as would be appreciated by one of skill in the art.

Embodiments of the present disclosure are described in detail herein with reference to embodiments thereof as illustrated in the accompanying drawings, in which like reference numerals are used to indicate identical or functionally similar elements. References to “one embodiment,” “an embodiment,” “some embodiments,” “in certain embodiments,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The examples are illustrative, but not limiting, of the present disclosure. Other suitable modifications and adaptations of the variety of conditions and parameters normally encountered in the field, and which would be apparent to those skilled in the art, are within the spirit and scope of the disclosure.

The term “or,” as used herein, is inclusive; more specifically, the phrase “A or B” means “A, B, or both A and B.” Exclusive “or” is designated herein by terms such as “either A or B” and “one of A or B,” for example.

The indefinite articles “a” and “an” to describe an element or component means that one or at least one of these elements or components is present. Although these articles are conventionally employed to signify that the modified noun is a singular noun, as used herein the articles “a” and “an” also include the plural, unless otherwise stated in specific instances. Similarly, the definite article “the,” as used herein, also signifies that the modified noun may be singular or plural, again unless otherwise stated in specific instances.

“Comprising” used herein as an open-ended transitional phrase. A list of elements following the transitional phrase “comprising” is a non-exclusive list, such that elements in addition to those specifically recited in the list may also be present. As used herein, a feature “consisting essentially of” or “composed essentially of” a list of elements is limited to the specified elements, plus other elements that do not materially affect the basic and novel characteristic(s) of the feature. As used herein, a feature “consisting of” or “composed entirely of” a list of elements is limited to the specified list, and excludes any elements not listed.

The term “wherein” is used as an open-ended transitional phrase, to introduce a recitation of a series of characteristics of the structure.

Where a range of numerical values is recited herein, comprising upper and lower values, unless otherwise stated in specific circumstances, the range is intended to include the endpoints thereof, and all integers and fractions within the range. It is not intended that the scope of the claims be limited to the specific values recited when defining a range. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. Finally, when the term “about” is used in describing a value or an end-point of a range, the disclosure should be understood to include the specific value or end-point referred to. Whether or not a numerical value or end-point of a range recites “about,” the numerical value or end-point of a range is intended to include two embodiments: one modified by “about,” and one not modified by “about.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

The present embodiment(s) have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

It is to be understood that the phraseology or terminology used herein is for the purpose of description and not of limitation. The breadth and scope of the present disclosure should not be limited by any of the above-described exemplary embodiments, but should be defined in accordance with the following claims and their equivalents.

1. A method, comprising:
mixing:
a solvent,
a thermally crosslinkable fluorine-containing polymer, and
one or more organic bases
to form a mixed solution;
depositing the mixed solution over a substrate to form a first layer;
crosslinking the first layer by thermal treatment to form a crosslinked first layer;
wherein:
the polymer is selected from: homopolymers of vinylidene fluoride; and
copolymers of vinylidene fluoride with fluorine-containing ethylenic monomers; and
the one or more organic bases each have a pKa of 10 to 14.

2. The method of claim 1, wherein the fluorine-containing polymer is a copolymer of vinylidene fluoride with one or more fluorine-containing ethylenic monomers.

3. The method of claim 2, wherein the one or more fluorine-containing ethylenic monomers are represented by formula (1) or formula (2):
CF₂═CF—R_{f1} (formula (1))
wherein:
R_{f1} is selected from: —F; —CF₃; and —OR_{f2}; and
R_{f2} is a perfluoroalkyl group having 1 to 5 carbon atoms;
CX₂═CY—R_{f3} (formula (2))
wherein:
X is —H, or —F, or a halogen atom;
Y is —H, or —F, or a halogen atom; and
R_{f3} is —H, or —F, a perfluoroalkyl group having 1 to 5 carbon atoms, or a polyfluoroalkyl group having 1 to 5 carbon atoms.

4. The method of claim 2, wherein the one or more fluorine-containing ethylenic monomers are selected from: tetrafluoroethylene (TFE), chlorotrifluoroethylene (CTFE),trifluoroethylene, hexafluoropropylene (HFP), trifluoropropylene, tetrafluoropropylene, pentafluoropropylene, trifluorobutene, tetrafluoroisobutene, perfluoro(alkyl vinyl ether) (PAVE), and combinations thereof.

5. The method of claim 1, wherein the fluorine-containing polymer is poly(vinylidene fluoride-co-hexafluoropropylene) (PVDF-HFP).

6. The method of claim 2, wherein the molar fraction of VDF units in the fluorine-containing polymer is 0.05 to 0.95.

7. The method of claim 1, wherein the one or more organic bases each have the formula: 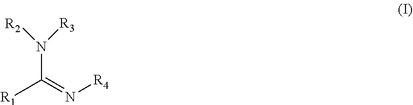
wherein:
the organic base has a molecular weight of 1000 or less;
R₁ and R₂ form a C₂-C₁₂ alkylene bridge, or independently of one another are C₁-C₁₈ alkyls;
R₃ and R₄, independent from R₁ and R₂, form a C₂-C₁₂ bridge, or independently of one another are C₁-C₁₈ alkyls.

8. The method of claim 1, wherein the one or more organic bases are selected from: 1,8-Diazabicyclo[5.4.0]undec-7-ene, (DBU); 1,5-Diazabicyclo[4.3.0]non-5-ene, (DBN); Tetramethylguanidine, (TMG); Triethylamine, (TEA); Hexamethylenediamine, (HMDA); Methylamine; Dimethylamine; Ethylamine; Azetidine; Isopropylamine; Propylamine; 1.3-Propanediamine; Pyrrolidine; N,N-Dimethylglycine; Butylamine; tert-Butylamine; Piperidine; Choline; Hydroquinone; Cyclohexylamine; Diisopropylamine; Saccharin; o-Cresol; δ-Ephedrine; Butylcyclohexylamine; Undecylamine; 4-Dimethylaminopyridine (DMAP); Diethylenetriamine; 4-Aminophenol; and combinations thereof.

9. The method of claim 1, wherein the one or more organic bases is 1,8-Diazabicyclo[5.4.0]undec-7-ene, (DBU).

10. The method of claim 1, wherein the weight ratio between the thermally crosslinkable fluorine-containing polymer and the one or more organic bases in the mixed solution is in the range 1000:2 to 1000:30.

11. The method of claim 10, wherein the weight ratio between the thermally crosslinkable fluorine-containing polymer and the one or more organic bases in the mixed solution is in the range 1000:2 to 1000:20.

12. The method of claim 1, wherein the mixed solution consists essentially of:
the solvent, the thermally crosslinkable fluorine-containing polymer, and the one or more organic bases.

13. The method of claim 1, wherein the mixed solution further comprises bisphenol-AF.

14. The method of claim 1, wherein the thermal treatment comprises exposing the first layer to a temperature of 80° C. to 170° C. for 0.5 to 5 hours.

15. The method of claim 1, wherein the method is a method of forming a transistor, the method further comprising:
depositing an organic semiconductor over the substrate, before or after forming the crosslinked first layer, to form a second layer, such that the second layer is in direct contact with the crosslinked first layer;
forming a source and a drain in contact with the second layer, before or after forming the second layer, the source and drain defining the ends of a channel through the second layer;
forming a gate superposed with the channel, wherein the crosslinked first layer separates the gate from the second layer.

16. The method of claim 15, wherein the organic semiconductor is an organic semiconductor polymer comprising a diketopyrrolopyrrole fused thiophene polymeric material, wherein the fused thiophene is beta-substituted.

17. The method of claim 16, wherein the organic semiconductor polymer comprises the repeat unit of formula 1′ or 2′: 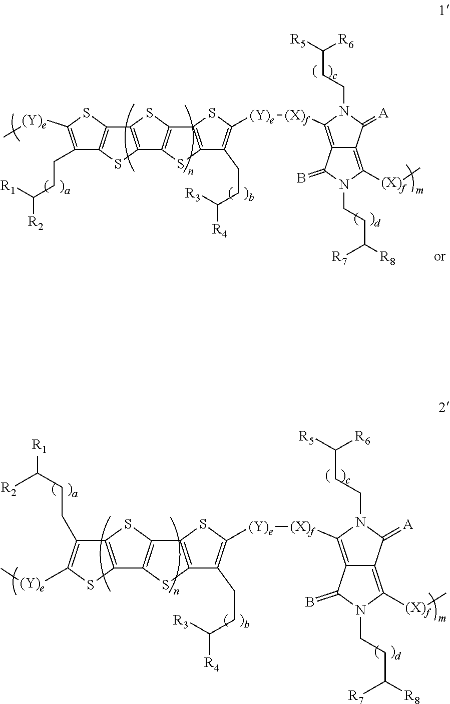
wherein, in the structure 1′ and 2′, m is an integer greater than or equal to one; n is 0, 1, or 2; R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl; a, b, c, and d are independently, integers greater than or equal to 3; e and f are integers greater than or equal to zero; X and Y are, independently a covalent bond, an optionally substituted aryl group, an optionally substituted heteroaryl, an optionally substituted fused aryl or fused heteroaryl group, an alkyne or an alkene; and A and B may be, independently, either S or O, with the provisos that:
i. at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl;
ii. if any of R₁, R₂, R₃, or R₄ is hydrogen, then none of R₅, R₆, R₇, or R₈ are hydrogen;
iii. if any of R₅, R₆, R₇, or R₈ is hydrogen, then none of R₁, R₂, R₃, or R₄ are hydrogen;
iv. e and f cannot both be 0;
v. if either e or f is 0, then c and d, independently, are integers greater than or equal to 5; and
vi. the polymer having a molecular weight, wherein the molecular weight of the polymer is greater than 10,000.

18. The method of claim 16, wherein the organic semiconductor is:

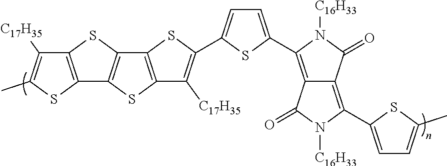

19. An apparatus, comprising: a crosslinked first layer disposed over a substrate, the crosslinked first layer formed by the process of:
mixing: a solvent; a thermally crosslinkable fluorine-containing polymer; and one or more organic bases to form a mixed solution;
depositing the mixed solution over a substrate to form a first layer;
crosslinking the first layer by thermal treatment to form a crosslinked first layer;
wherein:
the polymer is selected from: homopolymers of vinylidene fluoride; and copolymers of vinylidene fluoride with fluorine-containing ethylenic monomers; and
the one or more organic bases each have a pKa of 10 to 14.

20. The apparatus of claim 19, wherein the one or more organic bases is 1,8-Diazabicyclo[5.4.0]undec-7-ene, (DBU).

21. The apparatus of claim 19, wherein the apparatus is a transistor, the apparatus further comprising:
a second layer disposed over or under the crosslinked first layer, the second layer comprising an organic semiconductor, wherein the second layer is in direct contact with the crosslinked first layer;
a source and a drain in contact with the second layer, the source and drain defining the ends of a channel through the second layer; and
a gate superposed with the channel, wherein the crosslinked first layer separates the gate from the second layer.

22. The apparatus of claim 21, wherein the organic semiconductor is an organic semiconductor polymer comprising a diketopyrrolopyrrole fused thiophene polymeric material, wherein the fused thiophene is beta-substituted.

23. The apparatus of claim 22, wherein the organic semiconductor polymer comprises the repeat unit of formula 1′ or 2′: 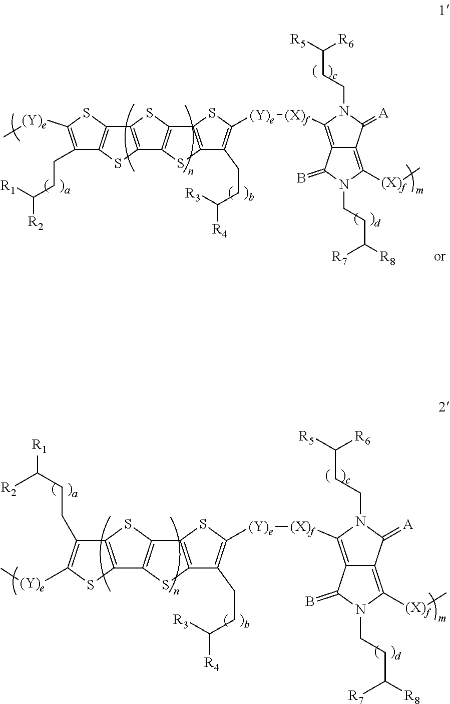
wherein, in the formula 1′ and 2′, m is an integer greater than or equal to one; n is 0, 1, or 2; R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl; a, b, c, and d are independently, integers greater than or equal to 3; e and f are integers greater than or equal to zero; X and Y are, independently a covalent bond, an optionally substituted aryl group, an optionally substituted heteroaryl, an optionally substituted fused aryl or fused heteroaryl group, an alkyne or an alkene; and A and B may be, independently, either S or O, with the provisos that:
i. at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl;
ii. if any of R₁, R₂, R₃, or R₄ is hydrogen, then none of R₅, R₆, R₇, or R₈ are hydrogen;
iii. if any of R₅, R₆, R₇, or R₈ is hydrogen, then none of R₁, R₂, R₃, or R₄ are hydrogen;
iv. e and f cannot both be 0;
v. if either e or f is 0, then c and d, independently, are integers greater than or equal to 5; and
vi. the polymer having a molecular weight, wherein the molecular weight of the polymer is greater than 10,000.

24. The apparatus of claim 23, wherein the organic semiconductor is:

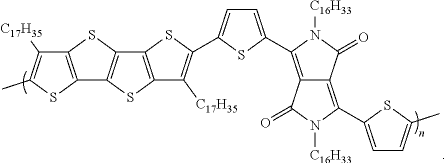

25. The apparatus of claim 24, wherein the capacitance of the transistor is independent from the thickness of the crosslinked first layer.
